(19) United States
(12) Patent Application Publication
(10) Pub. No.: US 2011/0259414 A1
(43) Pub. Date: Oct. 27, 2011

(54) REFLECTIVE ELECTRODE AND PHOTOELECTRIC ELEMENT

(76) Inventors: Jung-Shik Lim, Paju-si (KR); Seong-Kee Park, Goyang-si (KR); Jae-Hyun Kim, Paju-si (KR); Sun-Man Kim, Namyangju-si (KR); Tae-Young Lee, Seoul (KR); Min-Cheol Kim, Goyang-si (KR)

(21) Appl. No.: 13/089,904

(22) Filed: Apr. 19, 2011

(30) Foreign Application Priority Data
Apr. 26, 2010 (KR) 10-2010-0038305

(51) Int. Cl. H01L 31/0224; H01L 31/0236

(52) U.S. Cl. 136/256

(57) ABSTRACT

A reflective electrode which can be provided in a photoelectric element such as light emitting diode or solar cell is disclosed. The reflective electrode include a plurality of conductive material layers electrically connected with a semiconductor layer used as light absorbing layer or active layer of the photoelectric element; and at least one metal film arranged between neighboring two of the plurality of the conductive material layers. Here, the plurality of the conductive material layers are formed of a conductive material having a lower refraction index than a refraction index of the semiconductor layer, and one of the conductive material layers which directly contacts with the semiconductor layer is formed of a conductive material having a lower contact resistance than a contact resistance of a metal with the semiconductor layer.

### CROSS REFERENCE TO RELATED APPLICATION

This application claims the benefit of the Patent Korean Patent Application No. 10-2010-0038305, filed on Apr. 26, 2010, which is hereby incorporated by reference for all purposes as if fully set forth herein.

### BACKGROUND OF THE DISCLOSURE

1. Field of the Disclosure

The present invention relates to a reflective electrode with conductivity and reflectance and a photoelectric element including the reflective electrode.

2. Discussion of the Related Art

In general, a photoelectric element is a kind of a semiconductor configured of p-n junction, for example, a light-emitting diode including a light-emitting layer capable of emitting a light and a solar cell including a light-absorbing layer capable of converting a light energy absorbed therein into an electrical energy. Such a photoelectric element may typically include a reflect layer formed of a single metal material including aluminum (AL) or silver (Ag) or alloy of the two, with reflectance, in a surface in oppose to a light emitting passage or a light absorbing passage, in order to improve a quantity of light emitted or absorbed.

The solar cell included in the photoelectric element has the light absorbing layer configured of p-n junction and it converts a solar energy into an electrical energy by using a photoelectric effect generated by sunlight. The photoelectric effect is a phenomenon which electrodes inside a semiconductor material are excited by an optical energy and electron-hole pairs are generated, at this time, the electron and hole are moved by internal electric field toward opposite directions, respectively, thereby generating a photoelectron-motive force. Such a solar cell includes a crystalloid silicon solar cell and an amorphous silicon thin film solar cell. Rather than them, there may be a compound thin film solar cell, dye-sensitized solar cell and an organic thin film solar cell.

Out of them, the crystalloid silicon solar cell includes a solar absorption substrate formed in entire crystalloid silicon, having hundreds of micrometers (μm) thickness and thus it can absorb a light having a broad wavelength range. Because of that, the maximum conversion efficiency may be approximately 20%. The conversion efficiency means a rate of the amount of emitted electrical energy corresponding to the amount of the incident light energy.

In contrast, the thin film solar cell includes a light absorbing layer formed of a semiconductor material deposited as thin film having a predetermined micrometer thickness (μm) on a substrate selected from glass, metal plate and plastic which are less expensive than silicon, with a broader area. The thin film solar cell has an advantage of mass production and a disadvantage of low conversion efficiency, in comparison to the crystalloid silicon solar cell, because the light absorbing layer formed of amorphous silicon and having the predetermined micrometer (μm) thickness can transmit most lights having a long wavelength range.

Typically, the thin film solar cell includes the light absorbing layer configured to absorb a light energy to generate a photo-reactive carrier, and first and second electrodes in contact with and electrically connected with both surfaces (junctions) of the light absorbing layer, respectively, to apply the photo-reactive carrier thereto.

The first electrode is formed of a material having transmissivity and conductivity to transmit a light incident on the light absorbing layer (hereinafter, referenced to as ‘incident light’) there through and to apply a hole (or an electron) generated in the light absorbing layer thereto.

The light absorbing layer transmits most of the lights having a long wavelength range there though. To prevent optical trapping efficiency of the light absorbing layer from being lowered, the thin film solar cell may further include a reflective layer formed between the light absorbing layer and the second electrode to reflect the light transmitted via the light absorbing layer toward the light absorbing layer. The reflective layer may be formed of metal including aluminum (Al) or silver (Ag) known to have high reflectance.

The second electrode is formed of a conductive material and it is electrically connected with the light absorbing layer, to apply the electron (or hole) generated in the light absorbing layer thereto. When the reflective layer is formed of the conductive metal, the reflective layer may be provided as the second electrode or the second electrode may be electrically connected with the light absorbing layer via the reflective layer.

However, the reflective layer is formed with a broader area in contact with the light absorbing layer and it has a relatively large thickness, to reflect the light having a broad wavelength range at a preset reflectance value or more. Because of that, high contact resistance is generated between the light absorbing layer and the reflective layer. When the second electrode is integrally formed with the reflective layer or it is in contact with the reflective layer to be electrically connected with the light absorbing layer although the reflective layer is formed of the conductive material, a large quantity of photo-reactive carriers generated in the light absorbing layer might be lost at a border surface located between the light absorbing layer and the reflective layer before applied to the second electrode and thus the conversion efficiency of the solar cell might deteriorate.

To prevent this disadvantage, the second electrode may directly contact with the light absorbing layer via a contact hole formed in the reflective layer, to be electrically connected with the light absorbing layer. However, the second electrode is in contact with the light absorbing layer at a relatively small area corresponding to the contact hole, although the second electrode is directly in contact with the light absorbing layer via the contact hole. Because of that, a current density between the second electrode and the light absorbing layer may not be generated widely and uniformly.

As mentioned above, the conventional thin film solar cell absorbs the light incident on the light absorbing layer and the light reflected by the reflective light, to generate photo-reactive carriers. However, the conventional thin film solar cell has a disadvantage of limited conversion efficiency because the photo-reactive carriers are lost by high contact resistance between the reflective layer and the light absorbing layer.

### SUMMARY OF THE DISCLOSURE

Accordingly, the present invention is directed to a reflective electrode and a photoelectric element having the same.

An object of the present invention is to provide a reflective electrode which can reflect a light transmitted via a semiconductor layer used as light absorbing layer or light emitting layer toward the semiconductor layer, with a lower contact resistance with the semiconductor layer than a contact resistance between a metal and the semiconductor layer, and a photoelectric element including the reflective electrode, which can reduce photo-reactive carriers lost between the reflective electrode and the light absorbing layer and can have a current density generated widely and uniformly, only to enhance conversion efficiency for converting an optical energy into an electrical energy.

Additional advantages, objects, and features of the disclosure will be set forth in part in the description which follows and in part will become apparent to those having ordinary skill in the art upon examination of the following or may be learned from practice of the invention. The objectives and other advantages of the invention may be realized and attained by the structure particularly pointed out in the written description and claims hereof as well as the appended drawings.

To achieve these objects and other advantages and in accordance with the purpose of the invention, as embodied and broadly described herein, a reflective electrode includes a plurality of conductive material layers electrically connected with a semiconductor layer used as light absorbing layer or active layer of a photoelectric element; and at least one metal film arranged between neighboring two of the plurality of the conductive material layers. Here, the plurality of the conductive material layers may be formed of a conductive material having a lower refraction index than a refraction index of the semiconductor layer, and one of the conductive material layers which directly contacts with the semiconductor layer may be formed of a conductive material having a lower contact resistance with the semiconductor layer than a contact resistance between a metal and the semiconductor layer.

In another aspect of the present invention, a photoelectric element includes a substrate configured to transmit a light there through; a transparent electrode formed on the substrate to transmit the light there through; a light absorbing layer formed on the transparent electrode to generate a photo-reactive carrier by absorbing the light incident via the transparent electrode; and a reflective electrode formed on the light absorbing layer to reflect the light having transmitted via the light absorbing layer toward the light absorbing layer. Here, the reflective electrode may include a plurality of conductive material layers contacting to be electrically connected with the light absorbing layer; and at least one metal film arranged between neighboring two of the plurality of the conductive material layers. Also, the plurality of the conductive material layers may be formed of a conductive material having a lower refraction index than a refraction index of the light absorbing layer and one of the conductive material layers which directly contacts with the light absorbing layer is formed of a conductive material having a lower contact resistance than a contact resistance of a metal with the light absorbing layer.

According to the present invention, the reflective electrode includes the plurality of the conductive material layers contacting to be electrically connected with the semiconductor layer used as light absorbing layer or active layer of the photoelectric element, and the at least one metal film arranged between neighboring two of the plurality of the conductive material layers. The reflective electrode can reflect lights selectively according to each wavelength range by using drastic change of refraction index generated in each border surface of the conductive material layers and the metal films and plasma oscillation of the at least one metal film. One of the conductive material layers which directly contacts with the semiconductor layer is formed of a conductive material having a lower contact resistance than a contact resistance of a metal with the semiconductor layer. Because of that, the reflective electrode may be formed with a broad and uniform contact area with the semiconductor and thus the quantity of the carriers lost between the semiconductor layer and the reflective electrode may be reduced.

Furthermore, the photoelectric element according to the present invention includes the reflective electrode including the plurality of the conductive material layers contacting to be electrically connected with a light absorbing layer, and the at least one metal film arranged between neighboring two of the plurality of the conductive material layers. Because of that, according to the photoelectric element, the lights transmitted via the light absorbing layer, especially, the lights having a long wavelength range may be reflected by the reflective electrode to be re-incident on the light absorbing layer, only to enhance light trapping efficiency. Also, the quantity of the photo-reactive carriers lost between the light absorbing layer and the reflective electrode may be reduced, only to enhance the conversion efficiency for converting the optical energy into the electrical energy.

It is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of the disclosure and are incorporated in and constitute a part of this application, illustrate embodiment(s) of the disclosure and together with the description serve to explain the principle of the disclosure.

In the drawings:

FIG. 1 is a sectional view illustrating a reflective electrode according to an embodiment of the present invention;

FIGS. 2A and 2B illustrate an example of the reflective electrode shown in FIG. 1 and the result of simulation for a reflective characteristic of the reflective electrode;

FIG. 3 is a sectional view illustrating a reflective electrode according to another embodiment of the present invention;

FIGS. 4A to 4D illustrate a graph illustrating an example of a structure multilayered of a conductive material layer and a metal film and it illustrates the result of simulation for a reflective characteristic of the multilayered structure;

FIG. 5 is a sectional view illustrating a photoelectric element according to a first embodiment of the present invention;

FIG. 6 is a sectional view illustrating an operation example of the photoelectric element shown in FIG. 5; and

FIG. 7 is a sectional view illustrating a photoelectric element according to a second embodiment of the present invention.

### DESCRIPTION OF SPECIFIC EMBODIMENTS

Reference will now be made in detail to the specific embodiments of the present invention, examples of which are illustrated in the accompanying drawings. Wherever possible, the same reference numbers will be used throughout the drawings to refer to the same or like parts.

As follows, a reflective electrode and a photoelectric element according to exemplary embodiments of the present invention will be described in detail in reference to the accompanying drawings.

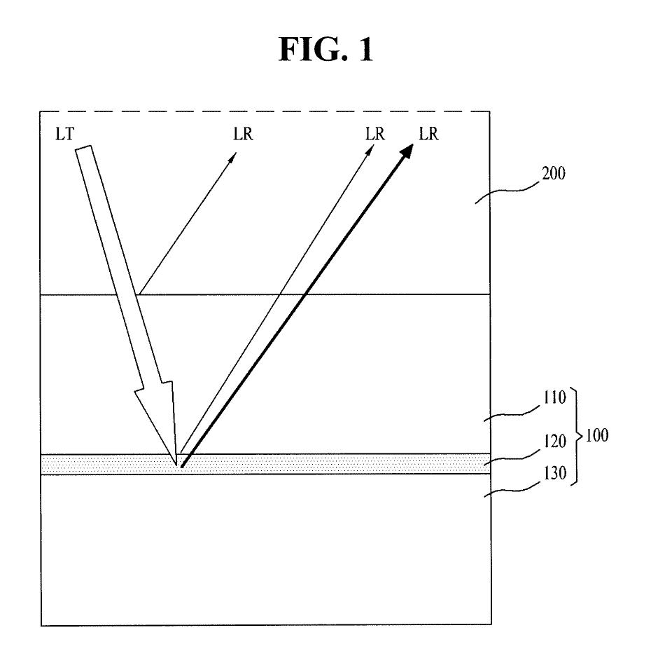

First of all, a reflective electrode according to an exemplary embodiment of the present invention will be described in detail in reference to FIGS. 1 to 4.

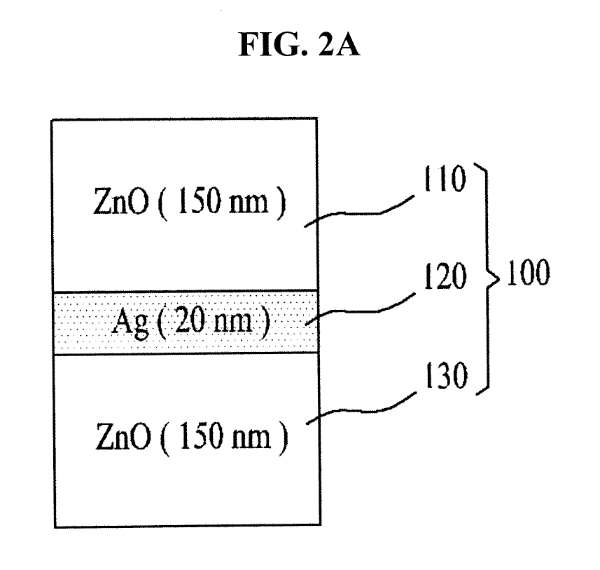

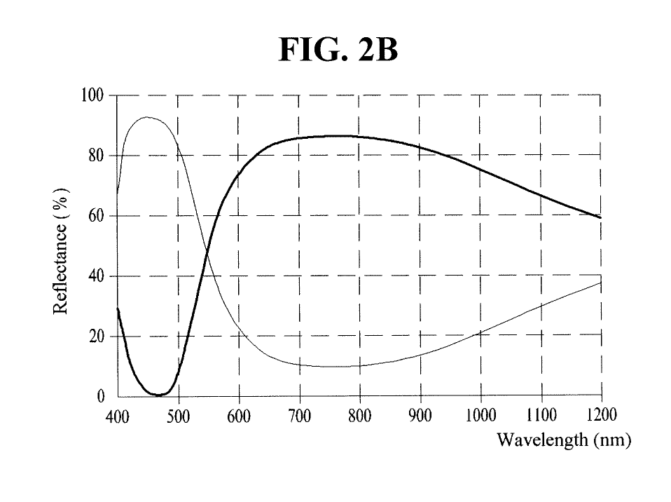

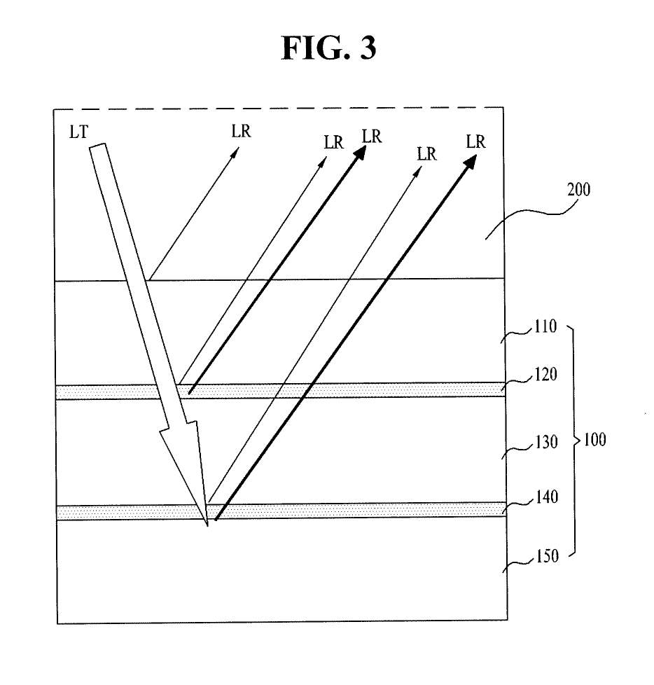

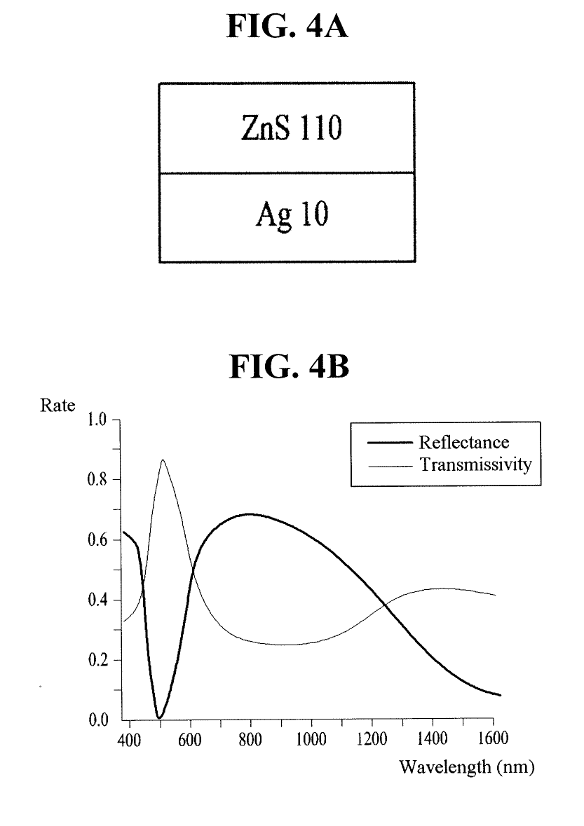

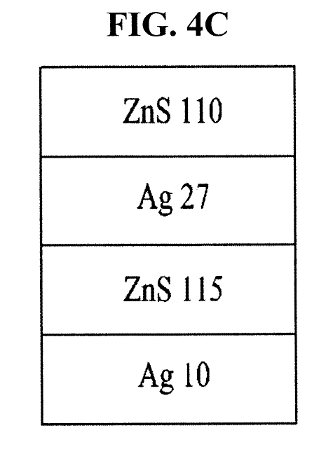

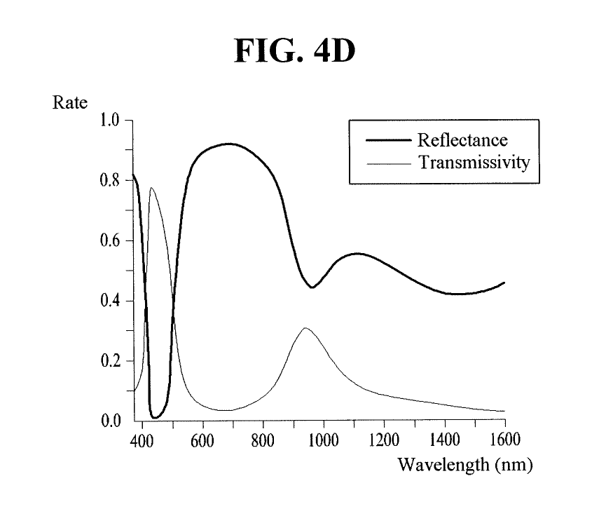

FIG. 1 is a sectional view illustrating a reflective electrode according to an embodiment of the present invention. FIGS. 2A and 2B illustrate an example of the reflective electrode shown in FIG. 1 and the result of simulation for a reflective characteristic of the reflective electrode. FIG. 3 is a sectional view illustrating a reflective electrode according to another embodiment of the present invention. FIG. 4 illustrates a graph illustrating an example of a structure multilayered of a conductive material layer and a metal film and it illustrates the result of simulation for a reflective characteristic of the multilayered structure.

The reflective electrode according to the embodiment of the present invention may be in contact and electrically connected with a semiconductor layer used as a light absorbing layer configured to generate a photo-reactive carrier by absorbing a light or an active layer emitting a light by re-combination of an injection carrier injected from the outside, and it may apply an injection carrier to the semiconductor layer or a photo-reactive carrier of the semiconductor layer thereto. Also, the reflective electrode may reflect the light transmitted via the semiconductor layer toward the semiconductor layer to improve the quantity of emitted lights or absorbed lights. Such the reflective electrode may include a plurality of conductive material layer in contact and electrically connected with the semiconductor layer, and at least one metal film arranged between neighboring two of the conductive material layers. In other words, the reflective electrode is formed of a multilayer structure having the conductive material layers and the at least one metal film alternated with each other.

Each of the conductive material layers is formed of a conductive material having a lower refraction index than a light absorbing layer. Especially, one of the conductive material layers which directly contacts with the semiconductor layer is formed of a conductive material having a lower contact resistance with the semiconductor layer than a contact resistance of a metal with the semiconductor layer. Each of the conductive material layers may be formed of one of ITO, FTO, GZO, ZnO, ZnS, GaN, InP, Si, alloy having Si, and Ge. Also, each of the conductive material layers is formed with a thickness of 500 nm or less to put an entire thickness of the reflective electrode into operation. The contact resistance between one of the conductive material layers which compose the reflective electrode, and the semiconductor layer, is lower than the contact resistance between the conventional metal and the semiconductor layer. Because of that, the reflective electrode may be formed in contact with a broad area of the semiconductor layer and a current density between the reflective electrode and the semiconductor layer may be generated widely and uniformly. The photo-reactive carriers or the injection carriers lost between the reflective electrode and the semiconductor layer may be reduced.

At least one metal film may be insertedly arranged between neighboring two of the conductive material layers and the metal film is formed of a metal with reflectance. In other words, the at least one metal film is formed of one of Au, Ag, Cu, Al, Pt and alloy including at least one of them.

The reflective electrode has the multilayer structure having the conductive material layers and the at least one metal film alternated with each other. Because of that, the refraction index is drastically changed at a border surface between the semiconductor layer and the conductive material layers and a border surface between the conductive material layers and the metal film, such that a predetermined part of the lights having passed the semiconductor layer may be reflected toward the semiconductor layer by the borders and further the plasma oscillation of the metal film. The plasma oscillation is generated by moving electron of the metal film induced by outside energy such as the incident light, with a oscillation frequency according to density of the electron.

The at least one metal film is formed thinner than the plurality of the conductive material layers. That is, the metal film with the thinner thickness may not affect conductivity of the reflective electrode. Because of that, the current density between the reflective electrode and the semiconductor layer may be prevented from deteriorating by the metal film and the photo-reactive carriers or injection carriers may be prevented from being lost between the reflective electrode and the semiconductor layer.

Especially, the at least one metal film is formed with a thickness of 2 nm or more to reflect a light at the border surface between the metal film and the conductive material layers. Alternatively, it is formed with a thickness of 50 nm or less to reflect one of the lights having passed the semiconductor layer which has a predetermined wavelength range selectively. As a result, the reflective electrode includes at least one metal film formed with a thickness of 2 nm or more and 50 nm or less, respectively. The metal film has a characteristic of reflecting a light having a predetermined wavelength corresponding to each of border surfaces, with transmitting a light having the other wavelength range.

Mentioned above, the reflective electrode according to this embodiment of the present invention reflects the light which reaches the reflective electrode after passing the semiconductor layer (hereinafter, referenced to as ‘transmitted light’) toward the semiconductor layer by using the drastic change of the refraction index at a border surface between the conductive material layers and at least one metal film further using the plasma oscillation of the metal film. A rate of the quantity of reflected lights to the quantity, of transmitted lights (hereinafter, ‘reflectance’) may be determined corresponding to the thickness of the at least one metal layer. Here, the reflectance of the reflective electrode and the thickness of the at least one metal film may not be in proportion to each other according to raw materials of the conductive material layers and the at least one metal film. The wavelength range of the lights reflected by the reflective electrode at a predetermined reflectance or more (hereinafter, referenced to as ‘reflected light’) is corresponding to the total number of the conductive material layers and the metal films which are alternatively multilayered. For example, as the layer number of the reflective electrodes is increasing, the number of the border surfaces is increasing and the wavelength range of the reflected light is then getting narrow. This is one of examples and the wavelength range of the reflected light may not be in proportion to the number of the layers composing the reflective electrode according to the materials and thickness of the conductive material layers and metal films. That is, the reflectance of the reflective electrode or the wavelength range of the light reflected by the reflective electrode may be random according to the materials or thickness of the conductive material layers and the at least one metal film. Because of that, the material or thickness of each conductive material layer and each metal film may be determined based on usage of the reflective electrode by experiments.

For example, as shown in FIG. 1, the reflective electrode 100 according to an embodiment of the present invention includes a first conductive material layer 110 directly contacting with to be electrically connected with a semiconductor layer 200 used as a light absorbing layer or light emitting layer of a photoelectric element, a metal film 120 contacting with to be electrically connected with the first conductive material layer 110, and a second conductive material layer 130 contacting with to be electrically connected with the metal film 120. The first and second conductive material layers 110 and 130 may be formed of a conductive material having a lower refraction index than the semiconductor layer 200. Especially, the first conductive material layer 110 may be formed of a conductive material having a lower contact resistance with the semiconductor layer 200 than a contact resistance between a metal and the semiconductor layer 200. For example, the first and second conductive material layers 110 and 130 may be formed of one of ITO, FTO, GZO, ZnO, ZnS, GaN, InP, Si, alloy including si, and Ge. To put an overall thickness of the reflective electrode into consideration, the first and second conductive material layers 110 and 130 are formed with a thickness of 500 nm or less which is larger than the thickness of the metal film 120.

That is, the metal film 120 is formed with a smaller thickness than the first conductive material layer 110 or the second conductive material layer 130. Especially, for the reflective electrode to have a predetermined reflectance and a characteristic of reflecting the light selectively, the metal film 120 may have a thickness of 2 nm or more and less than 50 nm. Such the metal film 120 is formed of a metal with reflectance, for example, one of Au, Ag, Cu, Al and Pt and alloy including at least one of them.

As shown in FIG. 1, the reflective electrode 100 having the above configuration reflects a light (LR) having a predetermined wavelength range out of transmitted light (LT) and transmits a light having the other wavelength range out of transmitted lights (LT), at a border surface between the semiconductor layer 200 and the first conductive material layer 110, a border surface between the first conductive material layer 110 and the metal film 120 and a border surface between the metal film 120 and the second conductive material layer 130.

In the meanwhile, a reflectance of the reflective electrode 100 and the wavelength range of the reflected light reflected by the reflective electrode 100 may be random according to the thickness and material of each of the first conductive material layer 110, the metal film 120 and the second conductive material layer 130. For example, as shown in FIG. 2A, in a structure of ZnO with a thickness of 150 nm (110, the first conductive material layer), Ag with a thickness of 20 nm (120, the metal film) and ZnO with a thickness of 150 nm (130, the second conductive material layer) which are multilayered sequentially, the result of simulation with respect to the reflectance corresponding to each wavelength shows that a reflectance corresponding to a wavelength range of approximately 400 nm˜500 nm and a wavelength range of approximately 620 nm˜950 nm, is 80% or more, as shown in FIG. 2B.

As shown in FIG. 3, the reflective electrode 100 according to another embodiment of the present invention may include a first conductive material layer 110 directly contacting with to be electrically connected with the semiconductor layer 200 used as the light absorbing layer or light emitting layer of the photoelectric element, a first metal film 120 contacting with to be electrically connected with the first conductive material layer 110, a second conductive material layer 130 contacting with to be electrically connected with the metal film 120, a second metal film 140 contacting to be electrically connected with the second conductive material layer 130, and a third conductive material layer 150 contacting to be electrically connected with the second metal film 140. The first, second and third conductive material layers 110, 130 and 150 may be formed of a conductive material having a lower refraction index than the semiconductor layer 200. Especially, the first conductive material layer 110 may be formed of a conductive material having a lower contact resistance with the semiconductor layer 200 than a contact resistance between a metal and the semiconductor layer 200. For example, the first, second and third conductive material layers 110, 130 and 150 may be formed of one of ITO, FTO, GZO, ZnO, ZnS, GaN, InP, Si, alloy including Si, and Ge. To put an overall thickness of the reflective electrode into consideration, the first, second and third conductive material layers 110, 130 and 150 are formed with a thickness of 500 nm or less which is larger than the thickness of each the first and second metal films 120 and 140.

The first and second metal films 120 and 140 are formed of a metal with reflectance. For example, the first and second metal films 120 and 140 are formed of one of Au, Ag, Cu, Al and Pt alloy including at least one of them. The first and second metal films 120 and 140 are formed with a smaller thickness than the first, second and third conductive material layers 110, 130 and 150. Especially, the first and second metal films 120 and 140 may have a thickness of 2 nm or more and less than 50 nm such that the reflective electrode may reflect the light selectively at a predetermined reflectance.

As shown in FIG. 3, the reflective electrode 100 having the above configuration reflects a light (LR) having a predetermined wavelength range of transmitted lights (LT) and transmits a light having the other wavelength range out of transmitted lights (LT), at a border surface between the semiconductor layer 200 and the first conductive material layer 110, a border surface between the first conductive material layer 110 and the first metal film 120, a border surface between the first metal film 120 and the second conductive material layer 130, a border surface between the second conductive material layer 130 and the second metal film 140 and a border surface between the second metal film 120 and the third conductive material layer 150.

In the meanwhile, as mentioned in reference to FIG. 1, the reflectance of the reflective electrode 100 and the wavelength range of the reflected light reflected by the reflective electrode 100 may be random according to the thickness and material of each of the first conductive material layer 110, the first metal film 120, the second conductive material layer 130, the second metal film 140 and the third conductive material layer 150. Because of that, the material or thickness of each of the first conductive material layer 110, the first metal film 120, the second conductive material layer 130, the second metal film 140 and the third conductive material layer 150 has to be determined based on usage of the reflective electrode by experiments.

For example, when comparing a multilayered structure of ZnS with a thickness of 110 nm and Ag with a thickness of 10 nm as shown in FIG. 4A, with a structure of ZnS with a thickness of 110 nm, Ag with a thickness of 27 nm, ZnS with a thickness of 115 nm and Ag with a thickness of 10 nm which are multilayered sequentially as shown in FIG. 4C, there may be difference reflection characteristics between the structures of FIGS. 4A and 4C as shown in FIGS. 4B and 4D. That is, when the transmitted light is moving from a top of ZnS in the structure of FIG. 4A, a wavelength range corresponding to a reflectance of 0.6 or more is approximately 650 nm ˜1000 nm, and the maximum reflectance is approximately 0.7. In contrast, when the transmitted light is moving from a top of ZnS with the thickness of 110 nm in the structure of FIG. 4C, a wavelength range corresponding to a reflectance of 0.6 or more is some of approximately 400 nm or less and approximately 500 nm˜900 nm and the maximum reflectance is approximately 0.9. Based on the result of the simulation, it may be expected that the maximum reflectance will be getting higher as the total number of the conductive material layers and the metal films is increasing in the reflective electrode having the conductive material layers formed of ZnS and the metal layers formed of Ag and that the wavelength range corresponding to the reflectance of 0.6 or more is getting narrower to be shifted rightward and leftward. Here, FIGS. 4A to 4D just show the result of simulation with respect to the reflection characteristic of the structure configured of the conductive material and the metal film respectively selected ZnS and Ag, and a different result will be achieved in a structure configured of different materials, different from FIGS. 4B and 4A.

As described above, the reflective electrode 100 according to the embodiment of the present invention has the structure of the plurality of the conductive material layers 110 and 130 and the metal film 120 which are alternatively multilayered, or the structure of the plurality of the conductive material layers 110, 130 and 150 and the at least one metal film 120 and 140 which are alternatively multilayered. As the refraction index is drastically changed at each border surface between the conductive material layers and the at least one metal film, the reflective electrode 100 selectively reflects the light having the wavelength range corresponding to the changed refraction index. Because of that, different from the conventional reflective layer, the reflective electrode 100 according to the present invention has the characteristic of selectively reflecting the light with the predetermined wavelength range at a predetermined reflectance or more. The reflective electrode 100 may be designed to include the conductive material layers 110, 130 and 150 and the at least one metal film 120 and 140 with an adjustable material and thickness according to a spec required by a photoelectric element to which the reflective electrode 100 will be applied. As a result, the reflective electrode 100 according to the present invention may be applicable to a variety of photoelectric elements.

The single conductive material layers 110 directly contacting with the semiconductor 200 out of the components composing the reflective electrode 100 may have a lower refraction index than the semiconductor layer 200, and it may be formed of a conductive material having a lower contact resistance with the semiconductor layer 200 than a contact resistance between a metal and the semiconductor material 200. Because of that, different from the conventional reflective layer formed of the metal, the reflective electrode 100 according to the present invention may contact with the semiconductor layer 200 at a broad area and a current density with the semiconductor layer 200 may be generated broadly and uniformly. Also, the photo-reactive carrier generated in the semiconductor layer 200 or the injected carriers which will be injected in the semiconductor layer 200 may be prevented from being lost.

Moreover, each of the at least one metal film 120 and 140 composing the reflective electrode 100 is surrounded by the conductive material layers 110, 130 and 150. An oxidation rate of the at least one metal film 120 and 140 may be slow down by the conductive material layers 110, 130 and 150. As a result, usage life of the photoelectric element may be enhanced.

As follows, a photoelectric element according to an embodiment of the present invention will be described. The photoelectric element according to this embodiment of the present invention includes the reflective electrode having the structure of the plurality of the conductive material layers and the at least one metal film which are alternatively multilayered as described above.

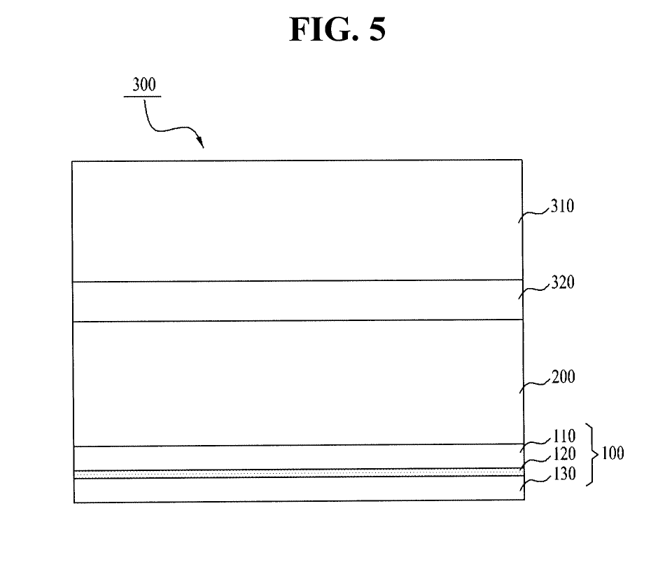

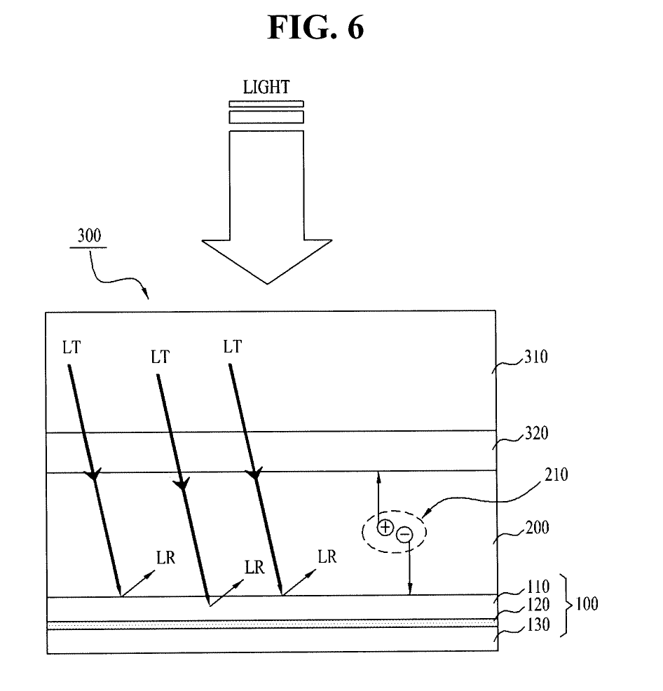

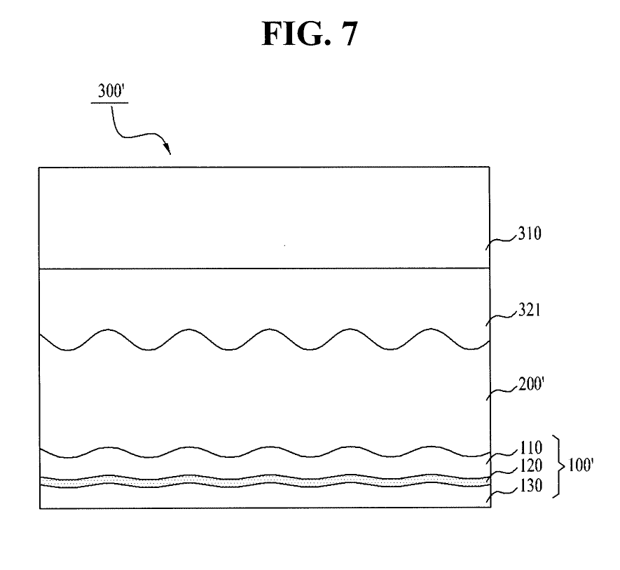

FIG. 5 is a sectional view illustrating a photoelectric element according to a first embodiment of the present invention and FIG. 6 is a sectional view illustrating an operational example of the photoelectric element shown in FIG. 5. FIG. 7 is a sectional view illustrating a photoelectric element according to a second embodiment of the present invention.

As shown in FIG. 5, a photoelectric element 300 according to a first embodiment of the present invention includes a substrate 310 having a light transmitted there through, a transparent electrode 320 formed on a surface of the substrate 310 to transmit the light there through, a semiconductor layer 200 (hereinafter, referenced to as ‘light absorbing layer’) formed on the transparent electrode 320 to generate a photo-reactive carrier by absorbing the light incident via the transparent electrode 320 (hereinafter, referenced to as ‘incident light’), and a reflective electrode 100 formed on the light absorbing layer 200 to reflect the light having transmitted the light absorbing layer 200 toward the light absorbing layer 200. The transparent electrode 320 contacts with a surface of the light absorbing layer 200 to be electrically connected with the light absorbing layer 200, such that the photo-reactive carrier generated in the light absorbing layer 200 may be applied. The reflective electrode 100 includes a plurality of conductive material layers 110 and 130 contacting to be electrically connected with another surface of the light absorbing layer 200, and at least one metal film 120 arranged neighboring two of the conductive material layers 110 and 130. Each of the conductive material layers 110 and 130 is formed of a conductive material having a lower refraction index than a refraction index of the light absorbing layer 200. One of the conductive material layers 110 and 130 which directly contacts with the light absorbing layer 200 may be formed of a conductive material having a lower contact resistance with the light absorbing layer 200 than a contact resistance of a metal with the light absorbing layer 200. Each of the at least one metal film 120 and 140 is formed thinner than each of the conductive material layers 110 and 130.

The substrate 310 is formed of a material with transmissivity such as glass or plastic.

The transparent electrode 320 is formed of a material with transmissivity and conductivity. For example, a first electrode 320 is formed of a metallic oxide of SnO₂, ZnO, In₂O₂ and TiO₂ or one of these metallic oxides having at least one of F, Sn, Al, Fe, Ga and Nb doped thereon. The transparent electrode 320 may have a structure of the at least one metallic oxide and the at least one metal film which are alternatively multilayered, and it may configured to transmit a light having a predetermined wavelength range there through selectively.

The light absorbing layer 200 has at least one of a structure of a p-semiconductor and an n-semiconductor joint with each other (hereinafter, referenced to as ‘p-n junction’) and a structure of a p-semiconductor, an i-semiconductor and an n-semiconductor joint with each other (hereinafter, referenced to as ‘p-i-n junction’). The light absorbing layer 200 may be formed of a thin film having a thickness of a few μm (more than 0 μm and less than 10 μm) to 500 μm. Typically, the light absorbing layer 200 is formed of at least one p-i-n junction. That is, the light absorbing layer 200 may be formed in a single p-i-n junction structure (referenced to as ‘single structure’) or a two p-i-n junction multilayered structure (referenced to as ‘tandem structure’) or three p-i-n junction multilayered structure (referenced to as ‘triple structure’).

The single structure light absorbing layer 200 has a limitation of absorbing only lights having a short wavelength range and it has a disadvantage of the smaller light trapping quantity. In contrast, the tandem structure light absorbing layer 200 includes a first p-i-n junction capable of absorbing a light having a short wavelength range and a second p-i-n junction capable of absorbing a light having a long wavelength range, only to have the greater lights trapping quantity than that of the single structure light absorbing layer. The triple structure light absorbing layer 200 includes a first p-i-n junction capable of absorbing a light having a short wavelength range and second and third p-i-n junctions capable of absorbing a light having a long wavelength range, only to have the greater lights trapping quantity than that of the single structure light absorbing layer or the tandem structure light absorbing layer. However, the tandem or triple structure light absorbing layer 200 has a disadvantage of the photo-reactive carrier loss at a border between the p-i-n junctions in comparison to the single structure light absorbing layer. At this time, the first p-i-n junction may be formed of amorphous silicon (a-Si) and the second and third p-i-n junctions may be formed of amorphous silicon-germanium (a-Si:Ge) or micro crystal silicon (micro c-Si).

As described above, the reflective electrode 100 includes the structure of the plurality of the conductive material layers 110 and 130 and the at least one metal film 120 (or further including third conductive material layer 150 and metal film 140 as shown in FIG. 3) which are alternatively multilayered thereon, with the thickness of a few μm (more than 0 μm and less than 10 μm) to 500 μm. At this time, the conductive material layers 110 and 130 may be formed of one of ITO, FTO, GZO, ZnO, ZnS, GaN, InP, Si, alloy including Si, and Ge. The at least one metal film 120 may be formed of a metal with reflectance, for example, one of Au, Ag, Cu, Al and Pt or alloy including at least one of them.

As shown in FIG. 6, the photoelectric element 300 according to the first embodiment allows a light incident thereon via the substrate 310 and the transparent electrode 320. Once an energy with an optical band gap or more is applied by the incident light, the photo-reactive carrier 210 is generated in the i-semiconductor layer (not shown) of the light absorbing layer 200 and an electron of the photo-reactive carrier is moved to the n-semiconductor layer (not shown) and a hole of the photo-reactive carrier is moved to the p-semiconductor layer (not shown), such that a photoelectron-motive force may be generated to convert an optical energy into an electrical energy. At this time, the transmitted light (LT) having passed the light absorbing layer 200 is reflected by the reflective electrode 100 to be re-incident on the light absorbing layer 200. That is, the light absorbing layer 200 further absorbs the reflected light (LR) by the reflective electrode and generates the photo-reactive carrier using the reflected light (LR). Because of that, the light trapping rate of the light absorbing layer 200 is enhanced by the reflective electrode 100, and the efficiency for converting the optical energy into the electrical energy (in other words, ‘conversion efficiency’) of the photoelectric element 300 may be enhanced.

As shown in FIG. 7, a photoelectric element 300′ according to a second embodiment of the present invention includes a substrate 310 having a light transmitted there through, a transparent electrode 321 formed on the substrate 310 to have a surface of a convexo-concave pattern for transmitting and scattering lights, a light absorbing layer 200′ formed on the transparent electrode 321 to generate a photo-reactive carrier by absorbing the light incident via the substrate 310 and the transparent electrode 321, and a reflective electrode 100′ formed on the light absorbing layer 200′ to reflect the light having transmitted the light absorbing layer 200′ toward the light absorbing layer 200′. The transparent electrode 321, the light absorbing layer 200′ and the reflective electrode 100′ may be multilayered on the substrate 310 sequentially. Because of that, the light absorbing layer 200′ and the reflective electrode 100′ layered on the transparent electrode 321 may be naturally formed in a smaller convexo-concave pattern by the convexo-concave pattern of the transparent electrode 321. The light having transmitted the substrate 310 is incident on the light absorbing layer 200′ in a state of being scattered by the transparent electrode 321. At least some part of the lights transmitted via the light absorbing layer may be scattered and reflected by the reflective electrode 100′ having the convexo-concave pattern. When the transmitted lights or the reflected lights are scattered by the transparent electrode 321 and the reflective electrode 100′ having the convexo-concave pattern, a light passage can be increased and light trapping chances of the light absorbing layer 200 can be increased. Because of that, the light trapping rate may be heightened and the conversion efficiency of the photoelectric element 300′ may be enhanced.

In the meanwhile, the photoelectric element 300′ according to the second embodiment of the present invention has identical configurations to the photoelectric element 300 according to the first embodiment of the present invention, except the convexo-concave patterns of the transparent electrode 321, the light absorbing layer 200′ and the reflective electrode 100′ which have the convexo-concave pattern, and repeated description will be omitted accordingly.

As described above, the photoelectric element according to the embodiments of the present invention may include the reflective electrode 100 or 100′ formed with the smaller thickness and the lower contact resistance with the light absorbing layer 200 or 200′, such that it may be formed as thin film element and that the efficiency for converting the optical energy into the electrical energy may be enhanced.

It will be apparent to those skilled in the art that various modifications and variations can be made in the present invention without departing from the spirit or scope of the inventions. Thus, it is intended that the present invention covers the modifications and variations of this invention provided they come within the scope of the appended claims and their equivalents.

What is claimed is:

1. A reflective electrode comprising:
a plurality of conductive material layers electrically connected with a semiconductor layer used as light absorbing layer or active layer of a photoelectric element; and
at least one metal film arranged between neighboring two of the plurality of the conductive material layers,
wherein the plurality of the conductive material layers are formed of a conductive material having a lower refraction index than a refraction index of the semiconductor layer, and
one of the conductive material layers which directly contacts with the semiconductor layer is formed of a conductive material having a lower contact resistance than a contact resistance of a metal with the semiconductor layer.

2. The reflective electrode of claim 1, wherein each of the at least one metal film is formed with a thinner thickness than those of the plurality of the conductive material layers.

3. The reflective electrode of claim 1, wherein each of the at least one metal film has a thickness of 2 nm or more and less than 50 nm.

4. The reflective electrode of claim 1, wherein a rate of the quantity of the lights reflected by each border surfaces between the plurality of conductive material layers and at least one metal film to the quantity of the lights transmitted via the semiconductor layer is corresponding to the thickness of the metal layer.

5. The reflective electrode of claim 1, wherein a wavelength range of a light reflected by each border surface between the plurality of the conductive material layers and the at least one metal film at a predetermined reflectance is corresponding to the total number of the plurality of the conductive material layers and the at least one metal film which are multilayered alternatively.

6. The reflective electrode of claim 1, wherein each of the plurality of the conductive material layers is formed of one of ITO, GZO, ZnO, ZnS, GaN, InP, Si, alloy including Si, and Ge.

7. The reflective electrode of claim 1, wherein each of the at least one metal film is formed of a single metal of Au, Ag, Cu, Al and Pt or alloy including at least one of the metals.

8. A photoelectric element comprising:
a substrate configured to transmit a light there through;
a transparent electrode formed on the substrate to transmit the light there through;
a light absorbing layer formed on the transparent electrode to generate a photo-reactive carrier by absorbing the light incident via the transparent electrode; and
a reflective electrode formed on the light absorbing layer to reflect the light having transmitted via the light absorbing layer toward the light absorbing layer,
wherein the reflective electrode comprises a plurality of conductive material layers contacting to be electrically connected with the light absorbing layer; and at least one metal film arranged between neighboring two of the plurality of the conductive material layers,
further wherein the plurality of the conductive material layers are formed of a conductive material having a lower refraction index than a refraction index of the light absorbing layer and one of the conductive material layers which directly contacts with the light absorbing layer is formed of a conductive material having a lower contact resistance than a contact resistance of a metal with the light absorbing layer.

9. The photoelectric element of claim 8, wherein the reflective electrode of claim 1, wherein each of the at least one metal film is formed with a thinner thickness than those of the plurality of the conductive material layers.

10. The photoelectric element of claim 8, wherein each of the at least one metal film has a thickness of 2 nm or more and less than 50 nm.

11. The photoelectric element of claim 8, wherein a rate of the quantity of the lights reflected by the reflective electrode to the quantity of the lights transmitted via the light absorbing layer is corresponding to the thickness of the metal film.

12. The photoelectric element of claim 8, wherein a wavelength of the light reflected by the reflective electrode at a predetermined reflectance is corresponding to the total number of the plurality of the conductive material layers and the at least one metal film.

13. The photoelectric element of claim 8, wherein the transparent electrode is formed with a top surface of a convexo-concave pattern, to scatter the light incident on the light absorbing layer via the substrate, and
the reflective electrode is formed with a surface of a predetermined pattern correspondingly formed by the convexo-concave pattern of the transparent electrode.

14. The photoelectric element of claim 8, wherein each of the plurality of the conductive material layers is formed of one of ITO, GZO, ZnO, ZnS, GaN, InP, Si, alloy including Si, and Ge.

15. The photoelectric element of claim 8, wherein each of the at least one metal film is formed of a single metal of Au, Ag, Cu, Al and Pt or alloy including at least one of the metals.
